(19) United States
(12) Patent Application Publication
(10) Pub. No.: US 2018/0278260 A1
(43) Pub. Date: Sep. 27, 2018

(54) BANDWIDTH ADJUSTMENT METHOD AND ASSOCIATED BANDWIDTH ADJUSTMENT CIRCUIT AND PHASE RECOVERY MODULE

(71) Applicant: MStar Semiconductor, Inc., Hsinchu Hsien (TW)

(72) Inventors: Ting-Nan CHO, Hsinchu Hsien (TW); Kai-Wen CHENG, Hsinchu Hsien (TW); Tai-Lai TUNG, Hsinchu Hsien (TW)

(21) Appl. No.: 15/909,113

(22) Filed: Mar. 1, 2018

(30) Foreign Application Priority Data
Mar. 22, 2017 (TW) 106109526

(51) Int. Cl. H03L 7/107; H03L 7/18; H03L 7/093

(52) U.S. Cl. CPC H03L 7/1075; H03L 7/0995; H03L 7/093; H03L 7/18

(57) ABSTRACT

A bandwidth adjustment method includes obtaining an upper bandwidth limit and a lower bandwidth limit according to an initial upper bandwidth limit and an initial lower bandwidth limit, obtaining an optimum bandwidth according to the upper bandwidth limit and the lower bandwidth limit, and adjusting the initial upper bandwidth limit and the initial lower and width limit according to the optimum bandwidth.

This application claims the benefit of Taiwan application Serial No. 106109526, filed on Mar. 22, 2017, the subject matter of which is incorporated herein by reference.

### BACKGROUND OF THE INVENTION

### Field of the Invention

The invention relates in general to a bandwidth adjustment method for a phase compensation adjustment circuit in a phase recovery module and associated bandwidth adjustment circuit and phase recovery module, and more particularly to a bandwidth adjustment method in response to a channel change and associated bandwidth adjustment circuit and phase recovery module.

### Description of the Related Art

A phase-locked loop (PLL) circuit generates a periodic output signal, which is expected to have a constant phase relationship with a periodic input signal. Based on characteristics (e.g., the frequency) of an input signal and circuit requirements, the bandwidth and damping coefficient of a PLL circuit need to be appropriately designed to obtain balance between a locking speed and a locking accuracy.

However, because characteristics of an input signal, under effects of environmental factors (e.g., noise), change with time, the performance of a PLL circuit may not be maintained at an optimum designed value if the bandwidth and damping coefficient of the PLL circuit are kept constant. Channel characteristics of a wireless communication also change with time, in a way that the optimum value needed by the PLL is also time variant. Therefore, there is a need for a solution for adaptively adjusting characteristics of a PLL circuit in response to channel changes in an operation of the PLL circuit.

### SUMMARY OF THE INVENTION

To solve the above issues, the present invention provides a bandwidth adjustment method and associated bandwidth adjustment circuit and phase recovery module.

The present invention provides a bandwidth adjustment method including: obtaining an upper bandwidth limit and a lower bandwidth limit according to an initial upper bandwidth limit and an initial lower bandwidth limit; obtaining an optimum bandwidth according to the upper bandwidth limit and the lower bandwidth limit; adjusting the initial upper bandwidth limit and the initial lower bandwidth limit according to the optimum bandwidth to obtain an adjusted initial upper bandwidth limit and an adjusted initial lower bandwidth limit; and adjusting the optimum bandwidth according to the adjusted initial upper bandwidth limit and the adjusted lower initial bandwidth limit.

The present invention further provides a bandwidth adjustment circuit including: a statistics circuit, recording a plurality of phase errors between an input signal that is compensated by a phase recovery module and a reference clock signal, and calculating a statistical value of the plurality of phase errors to generate a statistical indication signal; a control circuit, generating a bandwidth indication signal according to the statistical indication signal; and a conversion circuit, generating at least one filter coefficient of a working bandwidth of a phase compensation adjustment circuit in the phase recovery module according to the bandwidth indication signal.

The present invention further provides a phase recovery module including a multiplication circuit, a phase error detection circuit, a phase compensation adjustment circuit, and a bandwidth adjustment circuit. The bandwidth adjustment circuit obtains an upper bandwidth limit and a lower bandwidth limit according to an initial upper bandwidth limit and an initial lower bandwidth limit, obtains an optimum bandwidth according to the upper bandwidth limit and the lower bandwidth limit, adjusts the initial upper bandwidth limit and the initial lower bandwidth limit according to the optimum bandwidth to obtain an adjusted initial upper bandwidth limit and an adjusted lower bandwidth limit, and adjusts the optimum bandwidth according to the adjusted initial upper bandwidth limit and the adjusted initial lower bandwidth limit.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 is a block diagram of a phase recovery module according to an embodiment of the present invention;

FIG. 2 is a relationship diagram of a working bandwidth and a phase error according to an embodiment of the present invention;

FIG. 3 is a block diagram of the statistics circuit in FIG. 1 according to an embodiment;

FIG. 4 is a block diagram of the control circuit in FIG. 1 according to an embodiment;

FIG. 5 is a block diagram of the conversion circuit in FIG. 1 according to an embodiment;

FIG. 6 is a flowchart of a process according to an embodiment of the present invention; and

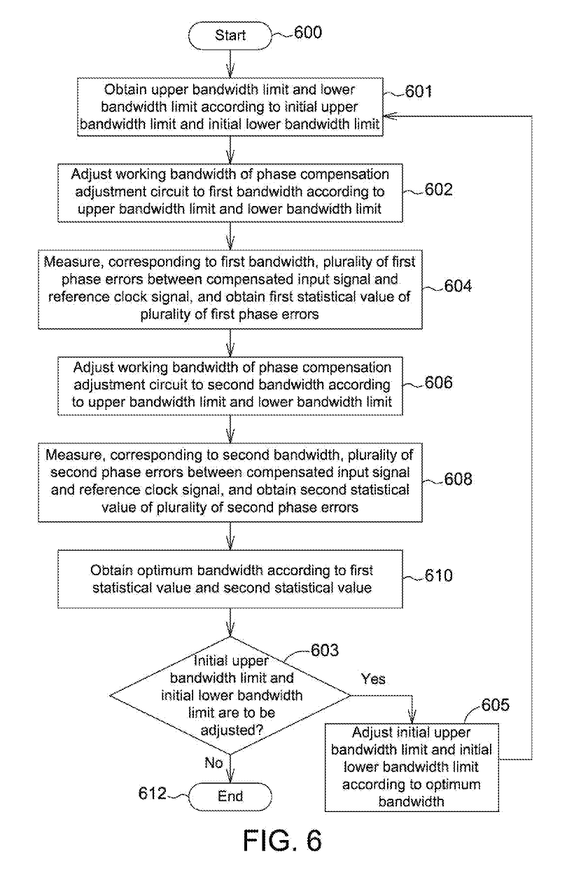

FIG. 7 is a schematic diagram of the initial bandwidth calculation circuit in FIG. 4 according to an embodiment.

### DETAILED DESCRIPTION OF THE INVENTION

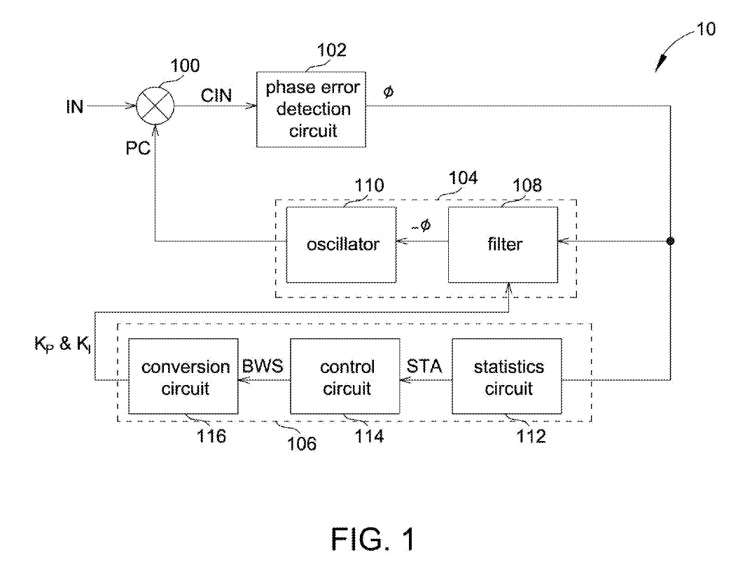

FIG. 1 shows a block diagram of a phase recovery module 10 according to an embodiment of the present invention. The phase recovery module 10 is applied to a communication system to compensate a phase error of an input signal IN. Referring to FIG. 1, the phase recovery module 10 includes a multiplication circuit 100, a phase error detection circuit 102, a phase compensation adjustment circuit 104 and a bandwidth adjustment circuit 106. The multiplication circuit 100 multiplies the input signal IN by a phase compensation signal PC to obtain a compensated input signal CIN. The phase error detection circuit 102 obtains a phase error Φ between the compensated input signal CIN and a reference clock signal (not shown in FIG. 1) in the communication system. The phase compensation adjustment circuit 104 includes a filter 108 and an oscillator 110, and adjusts the phase compensation signal PC according to the phase error Φ to minimize the phase error Φ. The bandwidth adjustment circuit 106 calculates a variance of the phase error Φ when the phase compensation adjustment circuit 104 operates in different bandwidths, and accordingly adjusts a working bandwidth BW_{F} of the phase compensation adjustment circuit 104. The working bandwidth BW_{F} of the phase compensation adjustment circuit 104 may be adaptively adjusted according to the time varying input signal IN to optimize the performance of the phase recovery module 10.

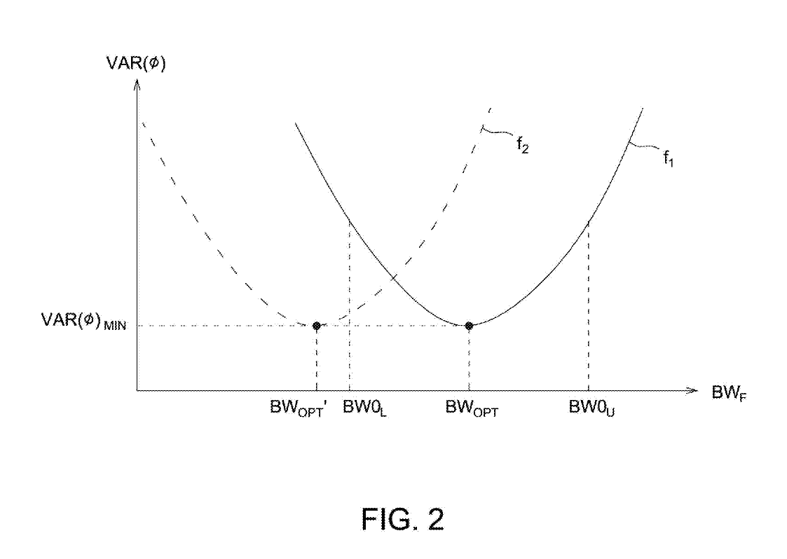

It should be noted that, not only the working bandwidth BW_{F} of the filter 108 affects the phase error Φ, but a corresponding relationship between a phase error variance VAR(Φ) and the working bandwidth BW_{F} also changes with time. FIG. 2 shows a relationship diagram of the working bandwidth BW_{F} and the phase error variance VAR(Φ) according to an embodiment of the present invention. Referring to FIG. 2, the solid line represents a corresponding relationship (represented by a function f₁) of the working bandwidth BW_{F} and the phase error variance VAR(Φ) at a time point t₁, and the dotted line represents a corresponding relationship (represented by a function f₂) of the working bandwidth BW_{F} and the phase error variance VAR(Φ) at a time point t₂. At the time point t₁, the phase error variance VAR(Φ) displays a convex function between an initial upper bandwidth limit BW0_{U} and an initial lower bandwidth limit BW0_{L}. That is to say, the phase error variance VAR(Φ) has a minimum phase error variance VAR(Φ)_{MIN} between the initial upper bandwidth limit BW0_{U} and the initial lower bandwidth limit BW0_{L}. If the working frequency BW_{F} of the filter 108 is adjusted to an optimum bandwidth BW_{OPT} corresponding to the minimum phase error variance VAR(Φ)_{MIN}, the phase recovery module 10 can obtain the optimum phase error Φ.

Thus, in an embodiment of the present invention, the bandwidth adjustment circuit 106 records the phase error variance VAR(Φ) of the phase recovery module 10 operating in different working bandwidths BW_{F}, so as to adjust the working bandwidth BW_{F} of the filter 108 to the optimum bandwidth BW_{OPT} corresponding to the minimum phase error variance VAR(Φ)_{MIN}. Further, the bandwidth adjustment circuit 106 may use a recursive algorithm to calculate the optimum bandwidth BW_{OPT} according to the initial upper bandwidth limit BW0_{U} and the initial lower bandwidth limit BW0_{L}.

Further, it should be noted that, the corresponding relationship between the phase error variance VAR(Φ) and the working bandwidth BW_{F} changes with time. In other words, the optimum bandwidth BW_{OPT} corresponding to the time point t₁ and another optimum bandwidth BW_{OPT}′ corresponding to the time point t₂ are different. In this situation, the bandwidth adjustment circuit 106 may again perform the recursive algorithm after a period of time from the time point t₁ (assuming t₂ is after a period of time from t₁) to calculate the optimum bandwidth BW_{OPT}′ corresponding to the time point t₂. To ensure that the result of again performing the recursive algorithm at the time t₂ is the optimum bandwidth BW_{OPT}′, the bandwidth adjustment circuit 106 may adjust the initial upper bandwidth limit and the initial lower bandwidth limit (with associated details of the adjustment described shortly) according to the optimum bandwidth BW_{OPT} obtained at the time point t₁ to obtain an adjusted initial upper bandwidth limit BW0_{U}′ and an adjusted initial lower bandwidth limit BW0_{L}′, and again perform the recursive algorithm according to the adjusted initial upper bandwidth limit BW0_{U}′ and the adjusted initial lower bandwidth limit BW0_{L}′ to calculate the optimum bandwidth BW_{OPT}′ corresponding to the time point t₂.

Operation details of how the bandwidth adjustment circuit 106 adjusts the working bandwidth BW_{F} of the filter 108 to the optimum bandwidth BW_{OPT} corresponding to the minimum phase error variance VAR(Φ), and calculates the optimum bandwidth by using the recursive algorithm according to the initial upper bandwidth limit and the initial lower bandwidth limit are given with an example below. When the phase recovery module 10 first starts to operate, a control circuit 114 in the bandwidth adjustment circuit 106 may adjust a bandwidth indication signal BWS according to the initial upper bandwidth limit BW0_{U} and the initial lower bandwidth limit BW0_{L} to indicate a bandwidth BM₁, which is between an upper bandwidth limit BW_{U} and a lower bandwidth limit BW_{L} and is obtained from interpolating the upper bandwidth limit BW_{U} and a lower bandwidth limit BW_{L}. In the first iteration of the recursive algorithm, the upper bandwidth limit BW_{U} is the initial upper bandwidth limit BU0_{U}, and the lower bandwidth limit BW_{L} is the initial lower bandwidth limit BW0_{L}. In one embodiment, the bandwidth BW₁ may be obtained from performing a first interpolation operation on the upper bandwidth limit BW_{U} and the lower bandwidth limit BW_{L}, and may be represented as:

BW₁=BW_{L}+C×(BW_{U}−BW_{L}) (1)

In equation (1), C is a constant between 1 and 0, and may equal to 0.61803. According to the bandwidth indication signal BWS that indicates the bandwidth BW₁, the conversion circuit 116 generates filter parameters K_{P} and K_{I} corresponding to the bandwidth BW₁ to the filter 108, so as to adjust the bandwidth of the filter 108 to BW₁. The filter parameters K_{P} and K_{I} are directly proportional to the bandwidth BW₁. In a situation where the bandwidth of the filter 108 is the bandwidth BW₁, the communication system starts receiving the input signal IN, and the multiplication circuit 100 adjusts the phase of the input signal IN according to the phase compensation signal PC to generate the compensated input signal CIN. According to the phase error Φ obtained by the phase error detection circuit 102, the filter 108 generates a phase compensation value (−Φ) to cause the oscillator 110 to adjust the phase compensation signal PC. At this point, the statistics circuit 112 records the phase error Φ as a phase error Φ₁ corresponding to the bandwidth BM₁. The statistics circuit 112 records the corresponding phase error Φ as the phase error Φ₁ each time the communication system samples the input signal IN. After obtaining a predetermined number of phase errors Φ₁, the statistics circuit 112 calculates a variance VAR₁ of the recorded phase error Φ₁, and transmits the variance VAR₁ through the statistical indication signal STA to the control circuit 114.

The control circuit 114 adjusts the bandwidth indication signal BWS to indicate another bandwidth BW₂, which is also between the upper bandwidth limit BW_{U} and the lower bandwidth limit BW_{L} and is obtained from interpolating the upper bandwidth limit BW_{U} and the lower bandwidth limit BW_{L}. In one embodiment, the bandwidth BW₂ may be interpolated from performing a second interpolation operation on the upper bandwidth limit BW_{U} and the lower bandwidth limit BW_{L}, and may be represented as:

BW₂=BW_{U}−C×(BW_{U}−BW_{L}) (2)

According to the bandwidth indication signal BWS that indicates the bandwidth BW₂, the conversion circuit 116 generates the filter parameters K_{P} and K_{I} corresponding to the bandwidth BW₂ to the filter 108, so as to adjust the bandwidth of the filter 108 to the bandwidth filter BW₂. In a situation where the bandwidth of the filter 108 is changed to the bandwidth BW₂, the communication system continues receiving the input signal IN, and the oscillator 110 continues adjusting the phase compensation signal PC according to the phase compensation value (−Φ) that the filter 108 generates. At this point, the statistics circuit 112 records the phase error Φ as a phase error Φ₂ corresponding to the bandwidth BW₂ when the bandwidth of the filter 108 is the bandwidth BW₂. After obtaining a predetermined number of phase errors Φ₂, the statistics circuit 112 calculates the variance VAR₂ of the phase errors Φ₂ recorded, and transmits the variance VAR₂ through the statistical indication signal STA to the control circuit 114.

After obtaining the variances VAR₁ and VAR₂, the control circuit 114 adjusts the bandwidth indication signal BWS according a relationship of the values of the variances VAR₁ and VAR₂, so as to optimize the working bandwidth BW_{F} of the filter 108.

In brief, when the variance VAR₁ is smaller than the variance VAR₂, the control circuit 114 may regard the bandwidth BW₂ calculated in the n^{th} iteration as the lower bandwidth limit BW_{L} of the (n+1)^{th} iteration; when the variance VAR₂ is smaller than the variance VAR₁, the control circuit 114 may regard the bandwidth BW₁ calculated in the n^{th} iteration as the upper bandwidth limit BW_{U} of the (n+1)^{th} iteration.

In other words, in each iteration, the control circuit 114 reduces the difference between the upper bandwidth limit BW_{U} and the lower bandwidth limit BW_{L}, and the bandwidth adjustment circuit 106 determines that the upper bandwidth limit and the lower bandwidth limit is approximate to the optimum bandwidth BW_{OPT} when the difference between upper bandwidth limit BW_{U} and the lower bandwidth limit BW_{L} is smaller than a threshold δ (i.e., convergence is reached). At this point, according to the upper bandwidth limit BW_{U} and the lower bandwidth limit BW_{L} of the current iteration (when convergence is reached), the bandwidth adjustment circuit 106 obtains the optimum bandwidth BW_{OPT} as the working bandwidth BW_{F} of the filter 108. Thus, the working bandwidth BW_{F} of the filter 108 is optimized, hence enhancing the operation performance of the phase recovery module 10.

Further, the method by which bandwidth adjustment circuit 106 obtains the optimum bandwidth BW_{OPT} according to the upper bandwidth limit BW_{U} and the lower bandwidth limit BW_{L} corresponding to the convergence is not limited. For example, the bandwidth adjustment circuit 106 may obtain the lower bandwidth limit BW_{L} corresponding to the convergence as the optimum bandwidth BW_{OPT} (BW_{OPT}=BW_{L}), obtain the upper bandwidth limit BW_{U} corresponding to the convergence as the optimum bandwidth BW_{OPT} (BW_{OPT}=BW_{U}), or calculate the optimum bandwidth BW_{OPT} by performing any interpolation operation on the lower bandwidth limit BW_{L} and the upper bandwidth limit BW_{U} as the optimum bandwidth BW_{OPT} (BW_{L}≤BW_{OPT}≤BW_{U}) when convergence is reached—these examples satisfy the requirements of the present invention and are regarded within the scope of the present invention.

Other operation details of the phase detection circuit 120, the phase compensation adjustment circuit 104 and the bandwidth adjustment circuit 106 in the phase recovery module 10 of the present invention can be referred from the phase error detection circuit 102, the PLL circuit 104 and the bandwidth adjustment circuit 106 disclosed in the Taiwan Patent No. 1605686 of the Applicant, and shall be omitted herein.

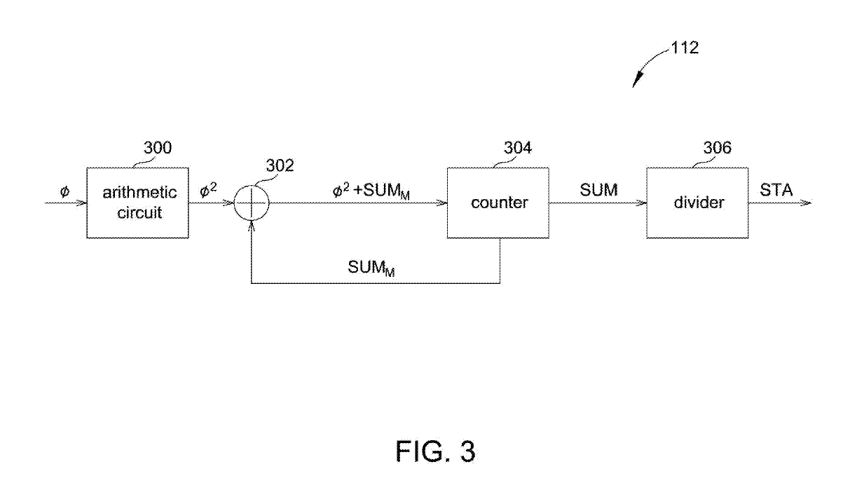

FIG. 3 shows a block diagram of the statistics circuit 112 in FIG. 1 according to an embodiment. In FIG. 3, the statistics circuit 112 includes an arithmetic circuit 300, an adder 302, a counter 304 and a divider 306. The arithmetic circuit 300 records the phase error Φ, and outputs the square of the phase error Φ (i.e., (Φ²) to the adder 302. The adder 302 adds Φ² with an intermediate sum SUM_{M}, and outputs the sum to the counter 304. The counter 304 counts the number of times of receiving the sum of Φ² and the intermediate sum SUM_{M}. When the number of times of receiving the sum of the Φ² and the intermediate sum SUM_{M} is smaller than a predetermined number, the counter 304 uses the sum of Φ² and the intermediate sum SUM_{M} as the new intermediate sum SUM_{M}, and outputs the new intermediate sum SUM_{M} to the adder 302. When the number of times of receiving the sum of Φ² and the intermediate sum SUM_{M} reaches the predetermined number, the counter uses the sum of Φ² and the intermediate sum SUM_{M} as the sum SUM to be outputted to the divider 306. The divider 306 receives the sum SUM and divides it by the predetermined number.

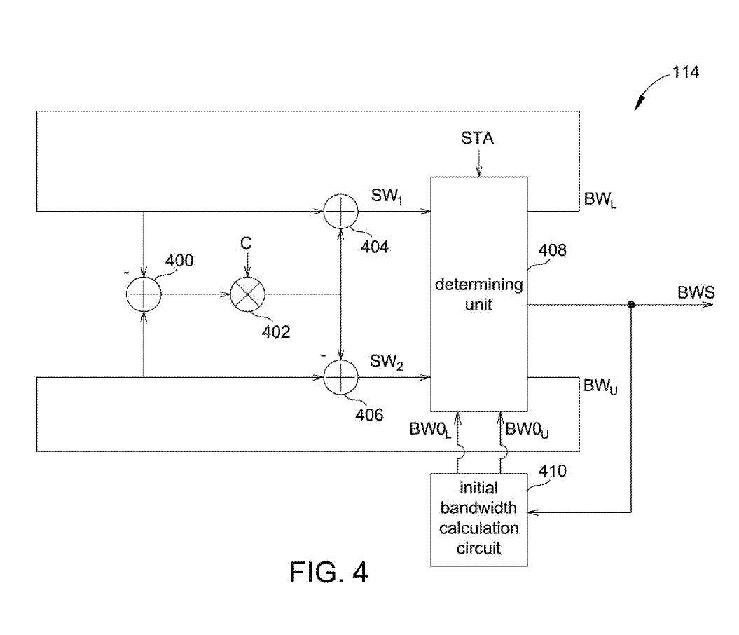

FIG. 4 shows a block diagram of the control circuit 114 in FIG. 1 according to an embodiment. As shown in FIG. 4, the control circuit 114 includes adders 400, 404 and 406, a multiplier 402, a determining unit 408 and an initial bandwidth calculation circuit 410. The adder 400 outputs the difference between the upper bandwidth limit BW_{U} and the lower bandwidth limit BW_{L} to the multiplier 402. The multiplier 402 calculates a product of the difference between the upper bandwidth limit BW_{U} and the lower bandwidth limit BW_{L} and a constant C, and sends the product to the adders 404 and 406. The adder 404 adds the lower bandwidth limit BW_{L} with the output of the multiplier 402 to generate the bandwidth BW₁, and the adder 406 subtracts the upper bandwidth limit BW_{U} by the output of the multiplier 402 to generate the bandwidth BW₂. According to the statistical indication signal STA, the determining unit 408 adaptive adjusts the upper bandwidth limit BW_{U}, the lower bandwidth limit BW_{L} and the bandwidth indication signal BWS. When the difference between the upper bandwidth limit BW_{U} and the lower bandwidth limit BW_{L} is smaller than the threshold δ, the determining unit 408 may adjust the bandwidth indication signal BWS to indicate the optimum bandwidth BW_{OPT}.

Further, the time point t₁ corresponds the time at which the time circuit 114 obtains the optimum bandwidth BW_{OPT}. The initial bandwidth calculation circuit 410 may, after the control circuit 114 obtains the optimum bandwidth BW_{OPT} for a predetermined period, again calculate the initial upper bandwidth limit and the initial lower bandwidth limit according to the optimum bandwidth BW_{OPT}, so as to obtain the adjusted initial upper bandwidth limit BW0_{U}′ and the adjusted initial lower bandwidth limit BW0_{L}′. Thus, the control circuit 114 may again perform the recursive algorithm according to the adjusted initial upper bandwidth limit BW0_{U}′ and the adjusted initial lower bandwidth limit BW0_{L}′ to calculate the optimum bandwidth BW_{OPT}′ corresponding to the time point t₂ (i.e., the time point after period from the time point t₁).

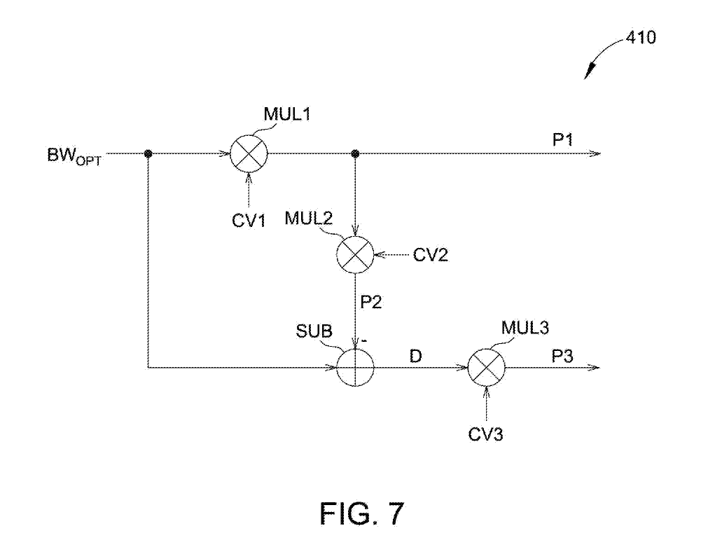

Ways for implementing the initial bandwidth calculation circuit 410 are not limited. For example, FIG. 7 shows a schematic diagram of the initial bandwidth calculation circuit in FIG. 4 according to an embodiment. As shown in FIG. 7, the initial bandwidth calculation circuit 410 includes multipliers MUL1, MUL2 and MUL3 and a subtractor SUB. The multiplier MUL1 multiples the optimum bandwidth BW_{OPT} by a first value CV1 to generate a first multiplication result P1. The multiplier MUL2 multiplies the first multiplication result P1 by a second value CV2 to generate a second multiplication result P2. The subtractor SUB subtracts the second multiplication result P2 from the optimum bandwidth BW_{OPT} to generate a subtraction result D. The third multiplier MUL3 multiplies the subtraction result D by a third value CV3 to generate a third multiplication result P3.

Depending on actual conditions, the initial bandwidth calculation circuit 410 may output the first multiplication result P1 or third multiplication result P3 as the adjusted initial upper bandwidth limit BW0_{U}′ and the adjusted initial lower bandwidth limit BW0_{L}′ For example, when a phase noise is smaller than a predetermined value or the communication system is experiencing an additive white Gaussian noise (AWGN) channel, the initial bandwidth calculation circuit 410 may output the first multiplication result P1 as the adjusted initial lower bandwidth limit BW0_{L}′, and output the third multiplication result P3 as the adjusted initial upper bandwidth limit BW0_{U}′. In other words, the initial bandwidth calculation circuit 410 may calculate the adjusted initial lower bandwidth limit BW0_{L}′ according to the optimum bandwidth BW_{OPT}, and calculate the adjusted initial upper bandwidth limit BW0_{U}′ according to the optimum bandwidth BW_{OPT} and the adjusted initial lower bandwidth limit BW0_{L}′. In one embodiment, the first value CV1 may be 2 raised to the n^{th} power (n≤0), the second value CV2 may be 0.61803, and the third value CV3 may be 1/(1−CV2) or 2.61801. Thus, if the adjusted initial lower bandwidth BW0_{L}′ and the adjusted initial upper bandwidth limit BW0_{U}′ is substituted into the first interpolation operation in equation (1), the first interpolation result obtained is the optimum bandwidth BW_{OPT}. That is, when the control circuit 114 again performs the recursive algorithm, the bandwidth BW₁ may be calculated as the optimum bandwidth BW_{OPT} (BW₁=BW_{OPT}), so as to ensure that the control circuit 114 is capable of correctly calculating the optimum bandwidth BW_{OPT}′.

On the other hand, when the phase noise is greater than a predetermined value, the initial bandwidth calculation circuit 410 may output the third multiplication result P3 as the adjusted initial lower bandwidth limit BW0_{L}′, and output the first multiplication result P1 as the adjusted initial upper bandwidth limit BW0_{U}′. In other words, the initial bandwidth calculation circuit 410 may calculate the adjusted initial upper bandwidth limit BW0_{U}′ according to the optimum bandwidth BW_{OPT}, and calculate the adjusted initial lower bandwidth limit BW0_{L}′ according to the optimum bandwidth BW_{OPT} and the adjusted initial upper bandwidth limit BW0_{U}′. In one embodiment, the first value CV1 may be 2 raised to the n^{th} power (0≤n≤0.69), the second value CV2 may be 0.61803, and the third value CV3 may be 1/(1−CV2) or 2.61803. Thus, if the adjusted initial lower bandwidth limit BW0_{L}′ and the adjusted initial upper bandwidth BW0_{U}′ are substituted into the second interpolation operation in equation (2), the second interpolation result obtained is the optimum bandwidth BW_{OPT}. That is, when the control circuit 114 again performs the recursive algorithm, the bandwidth BW₂ may be calculated as the optimum bandwidth BW_{OPT} (BW₂=BW_{OPT}), so as to ensure that the control circuit 114 is capable of correctly calculating the optimum bandwidth BW_{OPT}′.

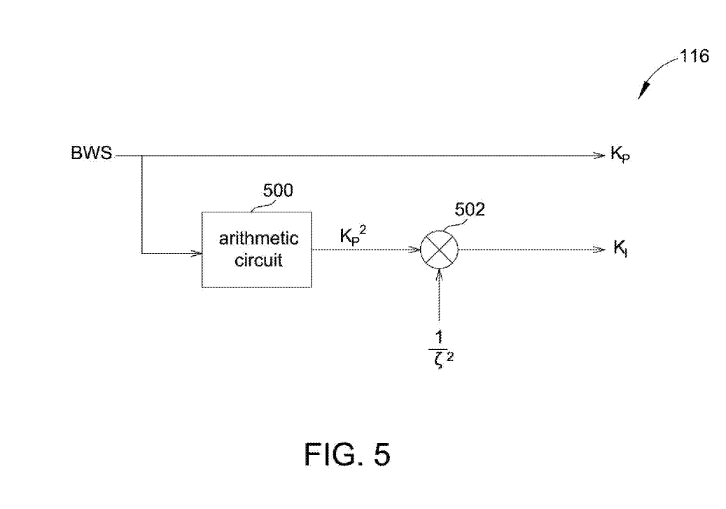

FIG. 5 shows a block diagram of the conversion circuit 116 in FIG. 1. In FIG. 5, the conversion circuit 116 includes an arithmetic circuit 500 and a multiplier 502. The conversion circuit 116 shown in FIG. 5 directly uses the bandwidth indication signal BWS as the filter coefficient K_{P} (i.e., the filter coefficient K_{P} is equal to the bandwidth indicated by the bandwidth indication signal BW_{S}), uses the arithmetic circuit 500 to calculate a square of the bandwidth indicated by the bandwidth indication signal BWS, and then uses the multiplier 502 to calculate a product of the square and a reciprocal of a square of a damping coefficient ζ as the filter coefficient

Operation details of the bandwidth adjustment circuit 106 may be concluded to a process 60. The process 60 includes following steps.

In step 600, the process 60 begins.

In step 601, according to an initial upper bandwidth limit and an initial lower bandwidth limit, an upper bandwidth limit and a lower bandwidth limit are obtained.

In step 602, according to the upper bandwidth limit and the lower bandwidth limit, an working bandwidth of the phase compensation adjustment circuit is adjusted to a first bandwidth.

In step 604, corresponding to the first bandwidth, a plurality of phase errors between a compensated input signal and a reference clock signal are measured, and a first statistical value of the first phase errors is obtained.

In step 606, according to the upper bandwidth limit and the lower bandwidth limit, the working bandwidth of the phase compensation adjustment circuit is adjusted to a second bandwidth.

In step 608, corresponding to the second bandwidth, a plurality of second phase errors between the compensated input signal and the reference clock signal are measured, and a second statistical value of the second phase errors is obtained.

In step 610, an optimum bandwidth is obtained according to the first statistical value and the second statistical value.

In step 603, it is determined whether the initial upper bandwidth limit and the initial lower bandwidth limit are to be adjusted. Step 605 is performed if so, otherwise step 612 is performed if not.

In step 605, the initial upper bandwidth limit and the initial lower bandwidth limit are adjusted according to the optimum bandwidth.

In step 612, the process 60 ends.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A bandwidth adjustment method, applied to a phase compensation adjustment circuit of a phase recovery module, comprising:
obtaining an upper bandwidth limit and a lower bandwidth limit according to an initial upper bandwidth limit and an initial lower bandwidth limit;
obtaining an optimum bandwidth according to the upper bandwidth limit and the lower bandwidth limit;
adjusting the initial upper bandwidth limit and the initial lower bandwidth limit according to the optimum bandwidth to obtain an adjusted initial upper bandwidth limit and an adjusted initial lower bandwidth limit; and
adjusting the optimum bandwidth according to the adjusted initial upper bandwidth limit and the adjusted initial lower bandwidth limit.

2. The bandwidth adjustment method according to claim 1, further comprising:
adjusting, according to the upper bandwidth limit and the lower bandwidth limit, a working bandwidth of the phase compensation adjustment circuit to a first bandwidth, wherein the first bandwidth is obtained by performing a first interpolation operation on the upper bandwidth limit and the lower bandwidth limit;
measuring, corresponding to the first bandwidth, a plurality of a first phase errors between a compensated input signal and a reference signal, and obtaining a first statistical value of the plurality of first phase errors, wherein the compensated input signal is obtained according to an input signal and a phase compensation signal generated by the phase compensation adjustment circuit;
adjusting, according to the upper bandwidth limit and the lower bandwidth limit, the working bandwidth of the phase compensation adjustment circuit to a second bandwidth, wherein the second bandwidth is obtained by performing a second interpolation operation on the upper bandwidth limit and the lower bandwidth limit;
measuring, corresponding to the second bandwidth, a plurality of second phase errors between the compensated input signal and the reference clock signal, and obtaining a second statistical value of the plurality of second phase errors; and
obtaining the optimum bandwidth according to the first statistical value and the second statistical value.

3. The bandwidth adjustment method according to claim 1, wherein the first bandwidth is greater than the second bandwidth, and the step of adjusting the working bandwidth according to the first statistical value and the second statistical value comprises:
when the first statistical value is smaller than the second statistical value, adjusting the lower bandwidth limit to the second bandwidth limit, and obtaining a third bandwidth by performing interpolation the upper bandwidth limit and the adjusted lower bandwidth limit, adjusting the bandwidth of the phase compensation adjusting circuit to the third bandwidth, measuring, corresponding to the third bandwidth, a plurality of third phase errors between the compensated input signal and the reference signal, obtaining a third statistical value of the plurality of third phase errors, and adjusting the working bandwidth according to the first statistical value and the third statistical value; and
when the second statistical value is smaller than the first statistical value, adjusting the upper bandwidth to the first bandwidth, obtaining a fourth bandwidth by performing interpolation on the adjusted upper bandwidth limit and the lower bandwidth limit, adjusting the bandwidth of the phase compensation adjustment circuit to the fourth bandwidth, measuring, corresponding to the fourth bandwidth, a plurality of fourth phase errors between the compensated input signal and the reference clock signal, obtaining a fourth statistical value of the plurality of fourth phase errors, and adjusting the working bandwidth according to the second statistical value and the fourth statistical value.

4. The bandwidth adjustment method according to claim 3, wherein the step of obtaining the optimum bandwidth comprises:
determining whether a first difference between the adjusted lower bandwidth limit and the adjusted upper bandwidth limit is smaller than a threshold; and
when the first difference is smaller than the threshold, obtaining the optimum bandwidth according to one of the adjusted lower bandwidth limit and the adjusted upper bandwidth limit.

5. The bandwidth adjustment method according to claim 1, further comprising:
determining whether to adjust the initial upper bandwidth limit and the initial lower bandwidth limit.

6. The bandwidth adjustment method according to claim 5, wherein the step of determining whether to adjust the initial upper bandwidth limit and the initial lower bandwidth limit comprises:
at a first time point, measuring, corresponding to the optimum bandwidth, a plurality of fifth phase errors between the compensated input signal and the reference clock signal, and obtaining a fifth statistical value of the plurality of fifth phase errors;
at a second time point, measuring, corresponding the optimum bandwidth, measuring a plurality of sixth phase errors between the compensated input signal and the reference clock, and obtaining a sixth statistical value of the plurality of sixth phase errors;
determining whether a second difference between the fifth statistical value and the sixth statistical value is greater than a predetermined value; and
determining that the initial upper bandwidth limit and the initial lower bandwidth limit are to be adjusted when second difference between the fifth statistical value and the sixth statistical value is greater than the predetermined value.

7. The bandwidth adjustment method according to claim 1, wherein the step of adjusting the initial upper bandwidth limit and the initial lower bandwidth limit according to the optimum bandwidth comprises:
calculating the adjusted lower initial bandwidth limit according to the optimum bandwidth; and
calculating the adjusted initial upper bandwidth limit according to the optimum bandwidth and the adjusted initial lower bandwidth limit.

8. The bandwidth adjustment method according to claim 7, wherein a first interpolation result obtained by performing the first interpolation operation on the adjusted initial lower bandwidth limit and the adjusted upper bandwidth limit is the optimum bandwidth.

9. The bandwidth adjustment method according to claim 1, wherein the step of adjusting the initial upper bandwidth limit and the initial lower bandwidth limit according to the optimum bandwidth comprises:
calculating the adjusted initial upper bandwidth limit according to the optimum bandwidth; and
calculating the adjusted initial lower bandwidth limit according to the optimum bandwidth and the adjusted initial upper bandwidth limit.

10. The bandwidth adjustment method according to claim 9, wherein a second interpolation result obtained from performing the second interpolation operation on the adjusted initial lower bandwidth limit and the adjusted initial upper bandwidth limit is the optimum bandwidth.

11. A bandwidth adjustment circuit, for a phase recovery module, comprising:
a statistics circuit, recording a plurality of phase errors between an input signal that is compensated by the phase recovery module and a reference signal, and calculating a statistical value of the plurality of phase errors to generate a statistical indication signal;
a control circuit, generating a bandwidth indication signal according to the statistical indication signal, wherein the bandwidth indication signal corresponds to an optimum bandwidth; and
a conversion circuit, generating at least one filter coefficient of a working bandwidth of a phase compensation adjustment circuit in the phase recovery module according to the bandwidth indication signal.

12. The bandwidth adjustment circuit according to claim 11, wherein the control circuit comprises:
a first adder, calculating a difference between an upper bandwidth limit and a lower bandwidth limit, wherein the upper bandwidth limit and the lower bandwidth limit are associated with an initial upper bandwidth limit and an initial lower bandwidth limit;
a first multiplier, calculating a product of the difference and a constant;
a second adder, calculating a sum of the lower bandwidth limit and the product as a first bandwidth;
a third adder, calculating a difference between the upper bandwidth limit and the product as a second bandwidth;
a determining unit, adjusting the upper bandwidth limit, the lower bandwidth limit and the bandwidth indication signal according to the statistical indication signal; and
an initial bandwidth calculation circuit, adjusting the initial upper bandwidth limit and the initial lower bandwidth limit according to the optimum bandwidth to obtain an adjusted initial upper bandwidth limit and an adjusted initial lower bandwidth limit.

13. The bandwidth adjustment circuit according to claim 12, wherein the initial bandwidth calculation circuit comprises:
a second multiplier, multiplying the optimum bandwidth by a first value to generate a first multiplication result;
a third multiplier, multiplying the first multiplication result by a second value to generate a second multiplication result;
a subtractor, subtracting the second multiplication result from the optimum bandwidth to generate a first subtraction result; and
a fourth multiplier, multiplying the first subtraction result by a third value to generate a third multiplication result;
wherein, one of the first multiplication result and the third multiplication result is one of the adjusted initial upper bandwidth limit and the adjusted initial lower bandwidth limit.

14. The bandwidth adjustment circuit according to claim 13, wherein the initial bandwidth calculation circuit outputs the adjusted initial lower bandwidth limit as the first multiplication result, and outputs the adjusted initial upper bandwidth limit as the third multiplication result.

15. The bandwidth adjustment circuit according to claim 13, wherein the initial bandwidth calculation circuit outputs the adjusted initial upper bandwidth limit as the first multiplication result, and outputs the adjusted initial lower bandwidth limit as the third multiplication result.

16. A phase recovery module, comprising:
a multiplication circuit, multiplying an input signal by a phase compensation signal to generate a compensated input signal;
a phase error detection circuit, detecting a phase difference between the compensated input signal and a reference clock signal;
a phase compensation adjustment circuit, generating the phase compensation signal according to the phase difference; and
a bandwidth adjustment circuit, comprising a statistics circuit, a control circuit and a conversion circuit; wherein, the bandwidth adjustment circuit obtains an upper bandwidth limit and a lower bandwidth limit according to an initial upper bandwidth limit and an initial lower bandwidth limit, obtains an optimum bandwidth according to the upper bandwidth limit and the lower bandwidth limit, adjusts the initial upper bandwidth limit and the initial lower bandwidth limit according to the optimum bandwidth to obtain an adjusted initial upper bandwidth limit and an adjusted lower bandwidth limit, and adjusts the optimum bandwidth according to the adjusted initial upper bandwidth limit and the adjusted initial lower bandwidth limit.

17. The phase recovery module according to claim 16, wherein the control circuit comprises:
a first adder, calculating a difference between an upper bandwidth limit and a lower bandwidth limit, wherein the upper bandwidth limit and the lower bandwidth limit are associated with an initial upper bandwidth limit and an initial lower bandwidth limit;
a first multiplier, calculating a product of the difference and a constant;
a second adder, calculating a sum of the lower bandwidth limit and the product as a first bandwidth;
a third adder, calculating a difference between the upper bandwidth limit and the product as a second bandwidth;
a determining unit, adjusting the upper bandwidth limit, the lower bandwidth limit and the bandwidth indication signal according to the statistical indication signal; and
an initial bandwidth calculation circuit, adjusting the initial upper bandwidth limit and the initial lower bandwidth limit according to the optimum bandwidth to obtain an adjusted initial upper bandwidth limit and an adjusted initial lower bandwidth limit.

18. The phase recovery module according to claim 17, wherein the initial bandwidth calculation circuit comprises:
a second multiplier, multiplying the optimum bandwidth by a first value to generate a first multiplication result;
a third multiplier, multiplying the first multiplication result by a second value to generate a second multiplication result;
a subtractor, subtracting the second multiplication result from the optimum bandwidth to generate a first subtraction result; and
a fourth multiplier, multiplying the first subtraction result by a third value to generate a third multiplication result;
wherein, one of the first multiplication result and the third multiplication result is one of the adjusted initial upper bandwidth limit and the adjusted initial lower bandwidth limit.

19. The phase recovery module according to claim 18, wherein the initial bandwidth calculation circuit outputs the adjusted initial lower bandwidth limit as the first multiplication result, and outputs the adjusted initial upper bandwidth limit as the third multiplication result.

20. The phase recovery module according to claim 18, wherein the initial bandwidth calculation circuit outputs the adjusted initial upper bandwidth limit as the first multiplication result, and outputs the adjusted initial lower bandwidth limit as the third multiplication result.
